(19) United States
(12) Patent Application Publication
(10) Pub. No.: US 2007/0007597 A1
(43) Pub. Date: Jan. 11, 2007

(54) ESD structure having different thickness gate oxides

(75) Inventors: Randy Yach, Phoenix, AZ (US); Philippe Deval, Lutry (CH)

Correspondence Address: BAKER BOTTS, LLP, 910 LOUISIANA, HOUSTON, TX, 77002-4995, US

(73) Assignee: Microchip Technology Incorporated

(21) Appl. No.: 11/215,775

(22) Filed: Aug. 30, 2005

Related U.S. Application Data
(60) Provisional application No. 60/697,187, filed on Jul. 7, 2005.

(51) Int. Cl. H01L 23/62

(52) U.S. Cl. 257/355

(57) ABSTRACT

An electrostatic discharge (ESD) structure having increased voltage withstand at an output terminal of an integrated circuit device has a thin gate oxide layer metal oxide semiconductor (MOS) device coupled in series with a thicker gate oxide layer MOS device. The thin gate oxide layer MOS device may be controlled by a low voltage control circuit of the integrated circuit. The thicker gate oxide layer MOS device may be coupled to an output of the integrated circuit device or a bipolar transistor may be coupled between the output of the integrated circuit device and the thicker gate oxide layer MOS device. The thin gate oxide layer and thicker gate oxide layer MOS devices may be coupled in series.

### RELATED PATENT APPLICATION

This application claims priority to commonly owned U.S. Provisional Patent Application Ser. No. 60/697,187; filed Jul. 7, 2005; entitled “Mixed-Thickness Oxide ESD Structure,” by Randy L. Yach and Philippe Deval; which is hereby incorporated by reference herein for all purposes.

### TECHNICAL FIELD

The present disclosure, according to one embodiment, relates to electrostatic discharge (ESD) protection of electronic circuits, more particularly, to ESD protection of input-out (I/O) circuits that may have to withstand higher operating voltages then normal integrated circuit logic voltages.

### BACKGROUND

Multiple circuits for controlling and sensing various functions in, for example but not limited to, vehicles are being replaced by bus interface devices at each electromechanical control/sensor in a vehicle. Having bus interfaces, e.g., Local Interconnect Network (LIN), Controller Area Network (CAN) and the like, greatly simplifies vehicle wiring and improves diagnostic troubling shooting of the vehicle's subsystems and operating components.

### SUMMARY

However, with any type of electromechanical interface, voltage spikes, over voltages and polarity changes must be dealt with by protecting the electronic input-output (I/O) portions of the bus interface. Additionally, vehicle electrical systems are going to higher operating voltages, e.g., 42 volts, because of the increased usage of electrical accessories in the vehicle. While integrated circuits are operating at lower and lower voltages because of smaller device elements resulting from improved miniaturization of the integrated circuit fabrication process.

According to a specific example embodiment of the present disclosure, an electrostatic discharge (ESD) structure having increased voltage withstand at an output terminal of an s integrated circuit may comprise at least one first metal oxide semiconductor (MOS) device having a thin gate oxide layer, wherein the at least one first MOS device is controlled by low voltage; at least one second MOS device having a thicker gate oxide layer than the thin gate oxide layer of the at least one first MOS device; an output terminal of an integrated circuit wherein the at least one second MOS device is coupled between the at least one first MOS device and the output terminal of the integrated circuit; wherein the at least one first and second MOS devices are interdigitated to form a parasitic bipolar transistor for electrostatic discharge protection at the output terminal.

According to another specific example embodiment of the present disclosure, an integrated circuit having at least one output terminal with an electrostatic discharge (ESD) structure having increased voltage withstand at the output terminal may comprise a bipolar transistor coupled to an output terminal of an integrated circuit; at least one first metal oxide semiconductor (MOS) device having a thin gate oxide layer, wherein the at least one first MOS device is controlled by a low voltage; at least one second MOS device having a thicker gate oxide layer than the thin gate oxide layer of the at least one first MOS device, wherein the at least one second MOS device is coupled between the at least one first MOS device and the bipolar transistor; wherein the at least one first and second MOS devices are interdigitated to form a parasitic bipolar transistor for electrostatic discharge protection at the bipolar transistor.

According to yet another specific example embodiment of the present disclosure, a method of fabricating in an integrated circuit an electrostatic discharge (ESD) structure having increased voltage withstand at an output terminal of the integrated circuit, said method may comprise forming at least one first metal oxide semiconductor (MOS) device having a thin gate oxide layer; forming at least one second MOS device having a thicker gate oxide layer than the thin gate oxide layer of the at least one first MOS device, wherein the at least one first and second MOS devices are interdigitated to form a parasitic bipolar transistor for electrostatic discharge protection of an output terminal.

According to still another specific example embodiment of the present disclosure, a method of fabricating in an integrated circuit an electrostatic discharge (ESD) structure having increased voltage withstand at an output terminal of the integrated circuit, said method may comprise forming a bipolar transistor; coupling the bipolar transistor to an output of an integrated circuit; forming at least one first metal oxide semiconductor (MOS) device having a thin gate oxide layer; forming at least one second MOS device having a thicker gate oxide layer than the thin gate oxide layer of the at least one first MOS device, wherein the at least one first and second MOS devices are interdigitated to form a parasitic bipolar transistor for electrostatic discharge protection of at the bipolar transistor.

### BRIEF DESCRIPTION OF THE DRAWINGS

A more complete understanding of the present disclosure thereof may be acquired by referring to the following description taken in conjunction with the accompanying drawing, wherein:

FIG. 1(a) illustrates a schematic circuit diagram of a prior technology output transistor structure;

FIG. 1(b) illustrates a schematic cross sectional view of the prior technology output transistor structure of FIG. 1(a);

FIG. 2(a) illustrates a schematic circuit diagram of an output transistor structure having MOS devices with different thickness gate oxides, according to a specific example embodiment of the present disclosure;

FIG. 2(b) illustrates a schematic cross sectional view of the output transistor structure of FIG. 2(a);

FIG. 3 illustrates a schematic top view of a portion of an integrated circuit comprising the MOS device structure shown in FIGS. 2(a) and 2(b); and

FIG. 4 illustrates a schematic diagram an output transistor structure having MOS devices with different thickness gate oxides and a bipolar transistor, according to another specific example embodiment of the present disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of example embodiments are schematically illustrated. Like elements in the drawings will be represented by like numbers, and similar elements will be represented by like numbers with a different lower case letter suffix.

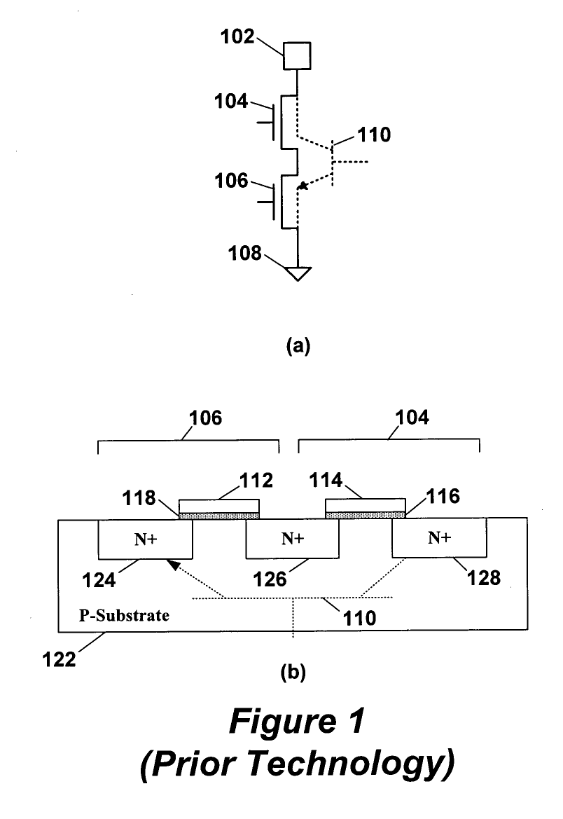

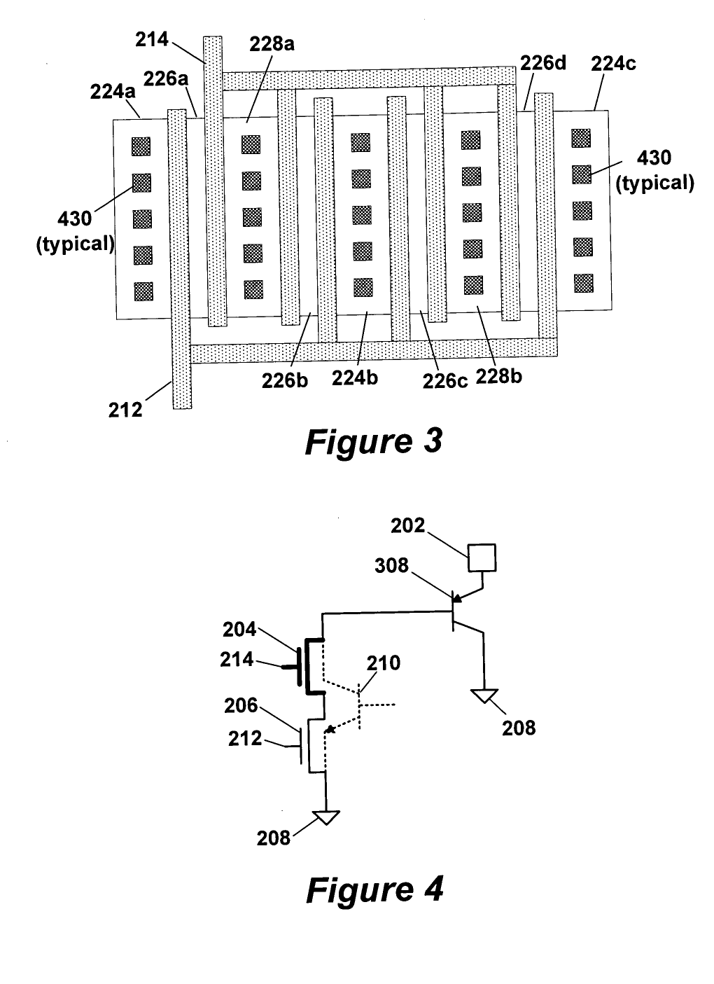

Referring to FIG. 1(a), depicted is a schematic circuit diagram of a prior technology output transistor structure of stacked (series connected) metal oxide semiconductor (MOS) devices 104 and 106 between an output 102 and a common supply or ground connection 108. Since the MOS devices 104 and 106 have substantially the same thin thickness gate oxides, they cannot safely handled a voltage level at the output 102 of more of then what the thin gate oxides are capable of handling. The MOS devices 104 and 106 are interdigitated (e.g., FIG. 3) and thereby may form a parasitic bipolar device 110 that may be used for ESD protection while sharing the voltage stress across the two MOS devices 104 and 106. This structural configuration may withstand slightly higher operating voltages than what a single thin thickness gate oxide MOS device could withstand by itself.

Referring to FIG. 1(b), depicted is a schematic cross sectional view of the prior technology output transistor structure of FIG. 1 (a). The N+ diffusion 124 may be the source of MOS device 106, the N+ diffusion 126 may be the drain of MOS device 106 and the source of MOS device 104, and the N+ diffusion 128 may be the drain of MOS device 104. The source of the MOS device 106 may be connected to the output power supply common 108 (through a metallization layer not shown) and the drain of the MOS device 104 may be connected to output 102 (through a metallization layer not shown). Since the N+ diffusions 124, 126 and 128 are interdigitated in the P− substrate 122, a parasitic bipolar device 110 may be formed therein. This bipolar device 110 may be used for ESD protection. Thin gate oxide 118 in combination with polysilicon conductor 112 may form a gate of the MOS device 106, and thin gate oxide 116 in combination with polysilicon conductor 114 may form a gate of the MOS device 104.

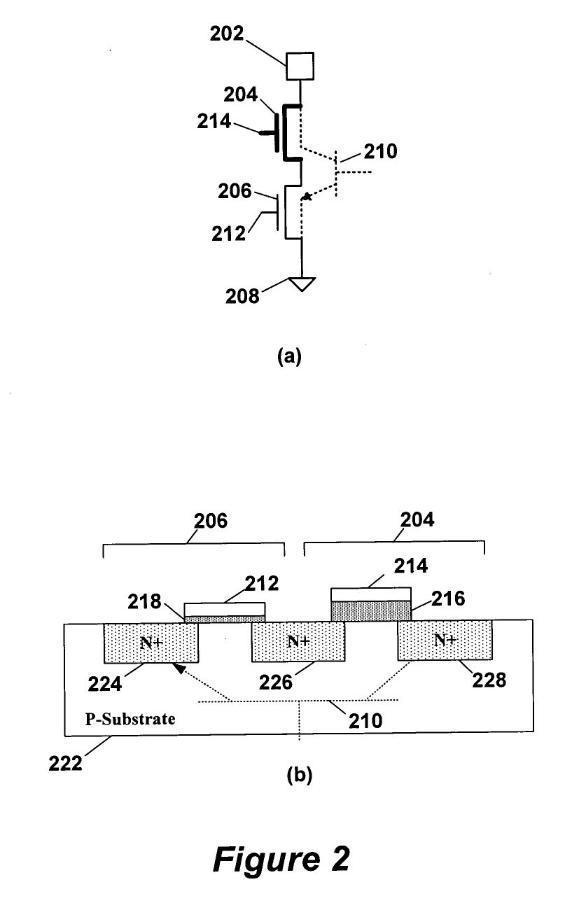

Referring now to FIG. 2(a), depicted is a schematic circuit diagram of an output transistor structure of stacked (series connected) metal oxide semiconductor (MOS) devices 204 and 206 having gate oxides of different thicknesses (e.g., one gate oxide is thicker than the other), according to a specific example embodiment of the present disclosure. The different thickness gate oxides ESD protection circuit may comprise a thin gate oxide MOS device 206 connected in series with a thicker gate oxide MOS device 204 that may be coupled to an output 202. The thin gate oxide MOS device 206 may have a low threshold voltage (V_{T}) that makes it easy to control with low voltage signals, e.g., control voltages of 3 volts or less at input 212. The thin gate oxide MOS device 206 may also have a lower breakdown voltage (V_{b}). The thicker gate oxide MOS device 204 may have a higher threshold voltage (V_{T}) and a higher breakdown voltage (V_{b}). The thicker gate oxide MOS device 204 allows a higher voltage withstand at the output 202 then the voltage that could be withstood at the prior technology output 102 (FIG. 1). During normal operation, a voltage level at input 214 keeps the thicker gate oxide MOS device 204 in saturation, e.g., input 214 greater than V_{T}. Then the thin gate oxide MOS device 206 may control operation of the output 202 even in a linear region (e.g., between saturation and cutoff).

Referring to FIG. 2(b), depicted is a schematic cross sectional view of the output transistor structure of FIG. 2(a). The N+ diffusion 224 may be the source of MOS device 206, the N+ diffusion 226 may be the drain of MOS device 206 and the source of MOS device 204, and the N+ diffusion 228 may be the drain of MOS device 204. The source of the MOS device 206 may be connected to the output power supply common 208 (through a metallization layer not shown) and the drain of the MOS device 204 may be connected to output 202 (through a metallization layer not shown). Since the N+ diffusions 224, 226 and 228 are interdigitated in the P− substrate 222, a parasitic bipolar device 210 may be formed therein. This bipolar device 210 may be used for ESD protection. Thin gate oxide 218 in combination with polysilicon conductor 212a may form a gate of the MOS device 206, and thicker gate oxide 216 in combination with polysilicon conductor 214a may form a gate of the MOS device 204. The MOS devices 204 and 206 are drawn physically close to each other and share a common source/drain N+ diffusion 226 to facilitate forming the parasitic bipolar device 210 that may be used for ESD protection. The MOS devices 204 and 206, output 202, and connections thereto may be formed on an integrated circuit substrate. Any type of MOS device may be used for the MOS devices 204 and 206, e.g., N-channel, P-channel, enhancement mode, depletion mode, etc.

Referring to FIG. 3, depicted is a schematic top view of a portion of an integrated circuit comprising the MOS device structure shown in FIGS. 2(a) and 2(b). The MOS devices 204 and 206 may be physically close to each other and share a common N+ diffusion 226 for the source and drain, respectively. This physical closeness also may facilitate forming a parasitic bipolar device 210 that may be used for ESD protection. Conductive vias 430 may connect the N+ wells 224 and 228 to their respective circuit nodes, e.g., power supply common 208, output 202 or transistor 308. There may be a plurality of MOS devices 204 and 206. Each of the plurality of MOS devices 204 may be coupled in parallel, and each of the plurality of MOS devices 206 may be coupled in parallel. The plurality of MOS devices 204 and 206 may be interdigitated to form parasitic bipolar transistors for electrostatic discharge protection.

Referring now to FIG. 4, depicted is a schematic diagram of an output transistor structure of cascode connected MOS devices 204 and 206 having gate oxides of different thicknesses (e.g., mixed-thickness gate oxides) and a bipolar transistor 308, according to another specific example embodiment of the present disclosure. The bipolar transistor 308 (e.g., PNP) may be coupled between the thicker gate oxide MOS device 204 and the output 202 for further voltage protection of the thin gate oxide MOS device 206. Furthermore the bipolar transistor 308 may be used to increase the drive capacity of the output 202. The bipolar transistor 308 may be used to increase drive current capability of the output 202, e.g., for a LIN bus and/or control device interface.

This disclosure teaches MOS device structures that may be used in any application to increase the voltage that the MOS device structure may sustain. However, the circuits according to the teachings of this disclosure may also be useful in any analog type output where high drive is needed in a linear region. For example, the thin gate oxide device 206 may have a higher drive capability in a smaller space than does the thicker gate oxide device 204. Further, if the gate of the thin gate oxide device 206 is controlled in the linear region, it will have even more gain as compared to the thicker gate oxide device 204. The thin gate oxide device 206, however, may not be used directly connected to a high voltage output 202 which also needs ESD protection. Thus the teachings of this disclosure may solve the problem of higher interface output operating voltage by adding the thicker gate oxide device 204, and ESD protection with the parasitic bipolar transistor 210 in one simple to fabricate integrated circuit MOS structure. A further improvement is shown in FIG. 4 where a bipolar output driver transistor 308 may be used for even higher gain. Thus MOS device designs may use a high gain thin gate oxide MOS device and still have adequate ESD protection on a high voltage input or output.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An electrostatic discharge (ESD) structure having increased voltage withstand at an output terminal of an integrated circuit, comprising:
at least one first metal oxide semiconductor (MOS) device having a thin gate oxide layer, wherein the at least one first MOS device is controlled by low voltage;
at least one second MOS device having a thicker gate oxide layer than the thin gate oxide layer of the at least one first MOS device;
an output terminal of an integrated circuit wherein the at least one second MOS device is coupled between the at least one first MOS device and the output terminal of the integrated circuit;
wherein the at least one first and second MOS devices are interdigitated to a form parasitic bipolar transistor for electrostatic discharge protection at the output terminal.

2. The ESD structure according to claim 1, wherein the at least one first MOS device is a plurality of first MOS devices, the at least one second MOS device is a plurality of second MOS devices, each of the plurality of first MOS devices are connected in parallel, and each of the plurality of second MOS devices are connected in parallel.

3. The ESD structure according to claim 2, wherein the plurality of first and second MOS devices are interdigitated to form parasitic bipolar transistors for electrostatic discharge protection at the output terminal.

4. The ESD structure according to claim 1, wherein the at least one first MOS device is connected in series with the at least one second MOS device.

5. The ESD structure according to claim 1, wherein the at least one first and second MOS devices are formed on a substrate of the integrated circuit.

6. The ESD structure according to claim 1, further comprising a bipolar transistor coupled between the output terminal and the at least one second MOS device.

7. The ESD structure according to claim 6, wherein the at least one first and second MOS devices and the bipolar transistor are formed on a substrate of the integrated circuit.

8. The ESD structure according to claim 6, wherein the bipolar transistor is a PNP bipolar transistor.

9. The ESD structure according to claim 1, wherein the at least one first and second MOS devices are P-channel MOS devices.

10. The ESD structure according to claim 1, wherein the at least one first and second MOS devices are N-channel MOS devices.

11. The ESD structure according to claim 1, wherein the at least one first and second MOS devices are enhancement mode MOS devices.

12. The ESD structure according to claim 13, wherein the at least one first and second MOS devices are depletion mode MOS devices.

13. The ESD structure according to claim 1, wherein the low voltage control circuit is three volts or less.

14. An integrated circuit having at least one output terminal with an electrostatic discharge (ESD) structure having increased voltage withstand at the output terminal, comprising:
a bipolar transistor coupled to an output terminal of an integrated circuit;
at least one first metal oxide semiconductor (MOS) device having a thin gate oxide layer, wherein the at least one first MOS device is controlled by a low voltage;
at least one second MOS device having a thicker gate oxide layer than the thin gate oxide layer of the at least one first MOS device, wherein the at least one second MOS device is coupled between the at least one first MOS device and the bipolar transistor;
wherein the at least one first and second MOS devices are interdigitated to form a parasitic bipolar transistor for electrostatic discharge protection at the bipolar transistor.

15. The integrated circuit according to claim 14, wherein the at least one first MOS device is a plurality of first MOS devices, the at least one second MOS device is a plurality of second MOS devices, each of the plurality of first MOS devices are connected in parallel, and each of the plurality of second MOS devices are connected in parallel.

16. The integrated circuit according to claim 15, wherein the plurality of first and second MOS devices are interdigitated to form parasitic bipolar transistors for electrostatic discharge protection at the bipolar transistor.

17. The integrated circuit according to claim 14, wherein the at least one first MOS device is connected in series with the at least one second MOS device.

18. The integrated circuit according to claim 14, wherein the at least one first and second MOS devices and the bipolar transistor are formed on a substrate of the integrated circuit.

19. A method of fabricating in an integrated circuit an electrostatic discharge (ESD) structure having increased voltage withstand at an output terminal of the integrated circuit, said method comprising:
forming at least one first metal oxide semiconductor (MOS) device having a thin gate oxide layer;
forming at least one second MOS devices having a thicker gate oxide layer than the thin gate oxide layer of the at least one first MOS device, wherein the at least one first and second MOS devices are interdigitated to a form parasitic bipolar transistor for electrostatic discharge protection of an output terminal.

20. The method according to claim 19, further comprising the steps of:
connecting in parallel a plurality of first MOS devices;
connecting in parallel a plurality of second MOS devices; and
coupling the plurality of second MOS devices between the plurality of first MOS devices and the output terminal.

21. The method according to claim 19, further comprising the step of controlling the at least one first MOS device with a low voltage control circuit.

22. The method according to claim 21, wherein the low voltage control circuit is three volts or less.

23. The method according to claim 19, wherein the at least one first MOS device is connected in series with the at least one second MOS device.

24. The method according to claim 19, further comprising the step of forming a bipolar transistor between the output terminal and the at least one second MOS device.

25. A method of fabricating in an integrated circuit an electrostatic discharge (ESD) structure having increased voltage withstand at an output terminal of the integrated circuit, said method comprising:
forming a bipolar transistor;
coupling the bipolar transistor to an output terminal of an integrated circuit;
forming at least one first metal oxide semiconductor (MOS) device having a thin gate oxide layer;
forming at least one second MOS device having a thicker gate oxide layer than the thin gate oxide layer of the at least one first MOS device, wherein the at least one first and second MOS devices are interdigitated to form a parasitic bipolar transistor for electrostatic discharge protection at the bipolar transistor.

26. The method according to claim 25, further comprising the steps of:
connecting in parallel a plurality of first MOS devices;
connecting in parallel a plurality of second MOS devices; and
coupling the plurality of second MOS devices between the plurality of first MOS devices and the bipolar transistor.

27. The method according to claim 25, further comprising the step of controlling the at least one first MOS device with a low voltage control circuit.

28. The method according to claim 25, wherein the at least one first MOS device is connected in series with the at least one second MOS device.
